(19) United States
(12) Patent Application Publication
(10) Pub. No.: US 2011/0072740 A1
(43) Pub. Date: Mar. 31, 2011

(54) CONCRETE PHOTOVOLTAIC SYSTEM

(76) Inventors: David B. Dieter, Visalia, CA (US); Zhenghao Wang, Hanford, CA (US)

(21) Appl. No.: 12/569,469

(22) Filed: Sep. 29, 2009

(51) Int. Cl. E04C 3/26; E04C 5/08; H01L 31/042

(52) U.S. Cl. 52/173.3; 52/223.1; 52/831

(57) ABSTRACT

A concrete photovoltaic structure includes an essentially vertical support member constructed, at least in part, of concrete, wherein the essentially vertical support member includes a first portion configured to be received, at least in part, within a footing. The concrete photovoltaic structure further includes a photovoltaic support member constructed, at least in part, of concrete, wherein the photovoltaic support member is configured to be affixed to a second portion of the essentially vertical support member.

### TECHNICAL FIELD

This disclosure relates to photovoltaic systems and, more particularly, to concrete photovoltaic systems.

### BACKGROUND

Conventional photovoltaic systems may generally be constructed out of steel and other similar lightweight materials to allow for ease of transport and assembly. Often, these conventional systems may be either cost-inefficient, structurally deficient, or both. It may often be useful for a photovoltaic system to provide a more structurally sound and cost effective means to construct a photovoltaic structure.

### SUMMARY OF DISCLOSURE

A concrete photovoltaic structure includes an essentially vertical support member constructed, at least in part, of concrete, wherein the essentially vertical support member includes a first portion configured to be received, at least in part, within a footing. The concrete photovoltaic structure further includes a photovoltaic support member constructed, at least in part, of concrete, wherein the photovoltaic support member is configured to be affixed to a second portion of the essentially vertical support member.

One or more of the following features may be included. A rigid joint assembly may be configured to rigidly couple the essentially vertical support member to the photovoltaic support member. The rigid joint assembly may include one or more sleeves that may be configured to receive one or more reinforcement members. At least one of the sleeves may be positioned within the photovoltaic support member and at least one of the reinforcement members may be configured to be positioned within the essentially vertical support member.

A gap may be defined between an outer periphery of at least one of the reinforcement members and an inner periphery of at least one of the sleeves into which the at least one reinforcement member may be positioned, wherein the gap may be configured to be filled with a bonding agent. The bonding agent may be a cementitious bonding agent.

The rigid joint assembly may be configured to provide non-perpendicular positioning of the photovoltaic support member with respect to the essentially vertical support member. A pivotable joint assembly may be configured to pivotally couple the essentially vertical support member to the photovoltaic support member. The pivotable joint assembly may include a first rigid joint assembly for rigidly affixing a first portion of the pivotable joint assembly to the photovoltaic support member. The pivotable joint assembly may further include a second rigid joint assembly for rigidly affixing a second portion of the pivotable joint assembly to the essentially vertical support member.

The essentially vertical support member may be a pre-cast concrete essentially vertical support member. The essentially vertical support member may be a pre-stressed concrete essentially vertical support member. The essentially vertical support member may include a plurality of obliquely angled support members, wherein the photovoltaic support member may be configured to be affixed to the plurality of obliquely angled support members. The plurality of obliquely angled support members may be constructed, at least in part, of metallic material. The footing may be a tubular footing. The photovoltaic support member may be constructed, at least in part, of pre-cast concrete. The photovoltaic support member may be constructed, at least in part, of pre-stressed concrete.

According to another implementation, a concrete photovoltaic structure includes an essentially vertical support member constructed, at least in part, of concrete, wherein the essentially vertical support member includes a first portion configured to be received, at least in part, within a footing. The concrete photovoltaic structure further includes a photovoltaic support member constructed, at least in part, of concrete, wherein the photovoltaic support member is configured to be affixed to a second portion of the essentially vertical support member. The concrete photovoltaic structure also includes a rigid joint assembly configured to rigidly couple the essentially vertical support member to the photovoltaic support member, wherein the essentially vertical support member is a pre-cast concrete essentially vertical support member.

One or more of the following features may be included. The rigid joint assembly may include one or more sleeves configured to receive one or more reinforcement members. At least one of the sleeves may be positioned within the photovoltaic support member and at least one of the reinforcement members may be configured to be positioned within the essentially vertical support member.

According to yet another implementation, a concrete photovoltaic structure includes an essentially vertical support member constructed, at least in part, of concrete, wherein the essentially vertical support member includes a first portion configured to be received, at least in part, within a footing. The concrete photovoltaic structure further includes a photovoltaic support member constructed, at least in part, of concrete, wherein the photovoltaic support member is configured to be affixed to a second portion of the essentially vertical support member. The concrete photovoltaic structure also includes a pivotable joint assembly configured to pivotally couple the essentially vertical support member to the photovoltaic support member, wherein the essentially vertical support member is a pre-cast concrete essentially vertical support member.

One or more of the following features may be included. The pivotable joint assembly may include a first rigid joint assembly for rigidly affixing a first portion of the pivotable joint assembly to the photovoltaic support member. The pivotable joint assembly may include a second rigid joint assembly for rigidly affixing a second portion of the pivotable joint assembly to the essentially vertical support member.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a diagrammatic view of a photovoltaic system.

FIG. 2 is an alternate diagrammatic view of the photovoltaic system of FIG. 1.

FIG. 3 is an alternate diagrammatic view of the photovoltaic system of FIG. 1.

FIG. 4 is an alternate diagrammatic view of the photovoltaic system of FIG. 1.

FIG. 5 is a diagrammatic view of a rigid joint assembly of the photovoltaic system of FIG. 1.

FIG. 6 is a diagrammatic view of sleeves and reinforcement members of the photovoltaic system of FIG. 1.

FIG. 7 is a diagrammatic view an alternative embodiment of the photovoltaic system of FIG. 1.

FIG. 8 is a diagrammatic view of a pivotable joint assembly of the photovoltaic system of FIG. 7.

FIG. 9 is a diagrammatic view of an alternative embodiment of the photovoltaic system of FIG. 1.

FIG. 10 is a diagrammatic view of an alternative embodiment of the photovoltaic system of FIG. 1.

FIG. 11 is an alternate diagrammatic view of the photovoltaic system of FIG. 1.

### DETAILED DESCRIPTION OF EXEMPLARY EMBODIMENTS

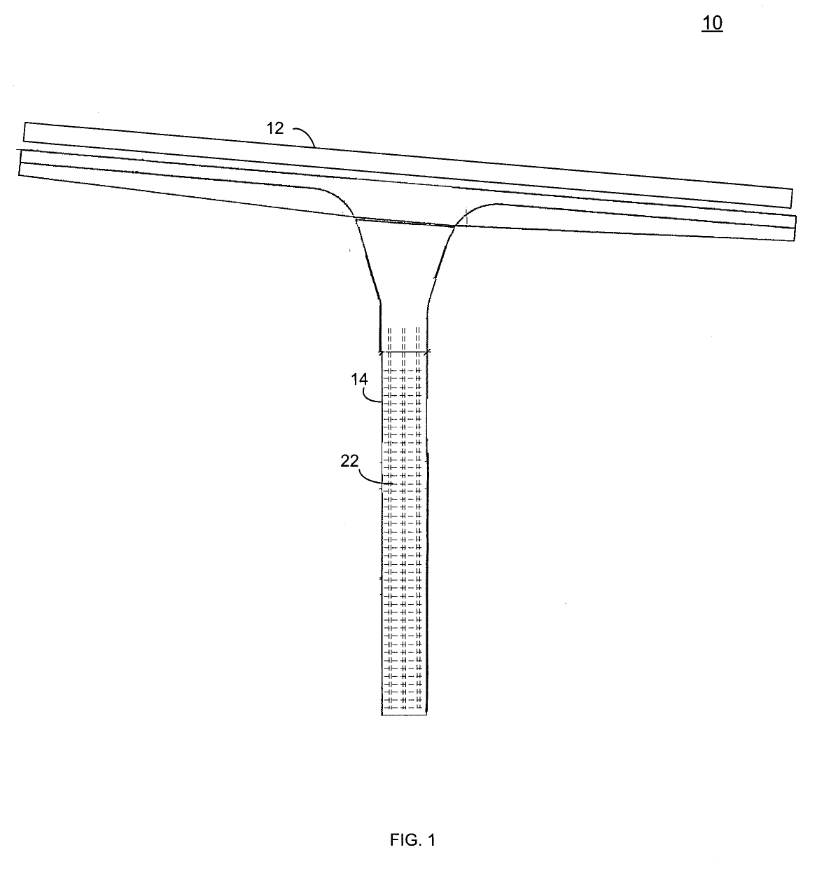

Referring to FIG. 1, there is shown a photovoltaic system 10 for supporting photovoltaic components 12 that may absorb energy from a light source (e.g., the sun). Examples of photovoltaic components 12 may include, but are not limited to: photovoltaic/solar cells, solar panels, solar modules, and photovoltaic arrays. As is known in the art, photovoltaic components 12 (e.g., solar cells) may be constructed using light absorbing materials that may enable the cell structure of photovoltaic components 12 to absorb photons and generate electrons via the photovoltaic effect. For example, solar cells may be constructed out of materials that may include, but are not limited to: crystalline silicon, cadmium telluride (CdTe), copper indium gallium selenide, amorphous silicon, and micromorphous silicon.

Photovoltaic system 10 may include an essentially vertical support member (e.g., essentially vertical support member 14) constructed, at least in part, of concrete. For the purposes of the following description, essentially vertical support member 14 may be described as being formed/molded into a tubular/beam shape. However, essentially vertical support member 14 may be formed/molded into any number of shapes including, but not limited to: oval, round, trapezoidal, and rectangular. Additionally, and as is known in the art, concrete may be a material composed of cement as well as other cementitious materials including, but not limited to: fly ash, slag cement, aggregate (e.g., gravel, limestone, granite, and sand), water, and chemical admixtures. Accordingly, and as described herein, essentially vertical support member 14 may be constructed of concrete and may be formed in the shape of a beam and/or column.

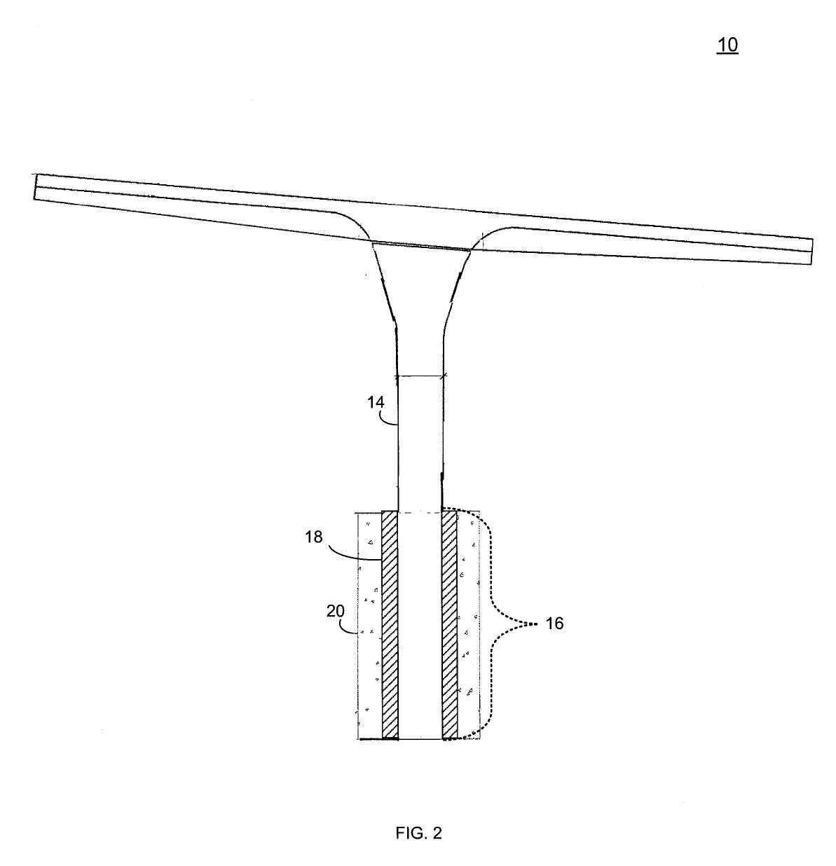

Additionally, and referring also to FIG. 2, the essentially vertical support member (e.g., essentially vertical support member 14) of, e.g., photovoltaic system 10, may include a first portion (e.g., first portion 16) that may be configured to be received, at least in part, within a footing (e.g., footing 18). Footing 18 may be a concrete-reinforced cavity in ground 20 into which first portion 16 of essentially vertical support member 14 may be received. For example, a hole may be bored in the earth that is larger than essentially vertical support member 14. Essentially vertical support member 14 may then be centered within the bored hole and plumbed. Concrete and/or other cementitious material may be subsequently used to fill the gap between the bored hole and essentially vertical support member 14, resulting in the formation of footing 18.

Additionally, essentially vertical support member 14 may be a pre-cast concrete essentially vertical support member. As is known by one of skill in the art, pre-cast concrete may be concrete that may have been cast in a reusable mould or form and cured in a controlled environment (and, e.g., later transported to a construction site). Further, mild reinforcement (e.g., steel reinforcement bars; hereinafter “rebar”) may be installed within pre-cast concrete to resist a given load in the event that the pre-cast concrete begins to fail.

Additionally/alternatively, essentially vertical support member 14 may be a pre-stressed concrete essentially vertical support member. As also known in the art, prestressed concrete may be utilized to overcome concrete's natural weakness in tension. It may be used to produce, e.g., beams, floors, or bridges with a longer span than may be practical with standard reinforced concrete (e.g., pre-cast concrete). As will be discussed in greater detail below, prestressing tendons (e.g., high tensile steel cable or rods) may be utilized to provide a clamping load that may produce a compressive stress, which may offset the tensile stress that the concrete compression member may otherwise experience due to a bending load.

As is known in the art, prestressed concrete may generally be constructed in one of three forms: pre-tensioned concrete, bonded post-tensioned concrete, or unbonded post-tensioned concrete. For the purposes of the present disclosure, pre-tensioned concrete may be discussed. However, this is not to be construed as a limitation of this disclosure, as other methods of prestressing may be utilized (e.g., bonded post-tensioned concrete, or unbonded post-tensioned concrete).

For example, the pre-tensioned concrete of, e.g., essentially vertical support member 14, may be cast around previously-tensioned tendons (e.g., essentially horizontal and vertical rebar 22). This method may produce a bond between essentially horizontal and vertical rebar 22 and the concrete, which may protect essentially horizontal and vertical rebar 22 from corrosion and may allow for direct transfer of tension. That is, as the concrete cures, it may adhere and bond to essentially horizontal and vertical rebar 22, thereby enabling the transfer of tension to the concrete when released (e.g., as compression via static friction).

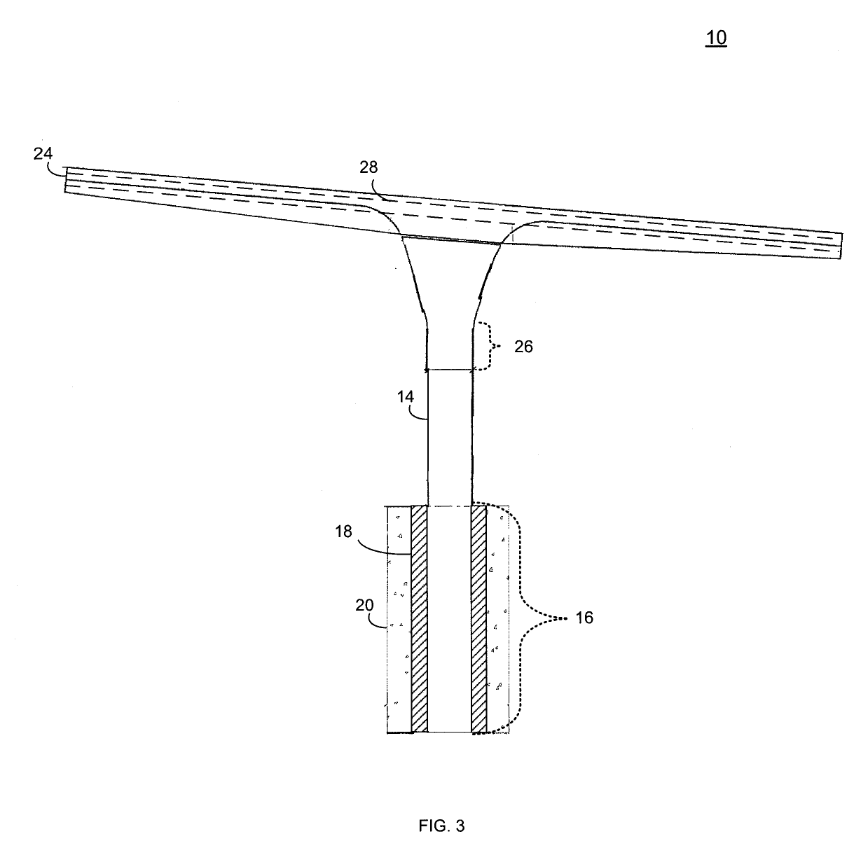

Referring also to FIG. 3, photovoltaic system 10 may also include a photovoltaic support member (e.g., photovoltaic support member 24) that may be constructed, at least in part, of concrete, wherein the photovoltaic support member may be configured to be affixed to a second portion (e.g., second portion 26) of the essentially vertical support member (e.g., essentially vertical support member 14). Similar to essentially vertical support member 14, the pre-tensioned concrete of, e.g., photovoltaic support member 24, may be cast around previously-tensioned tendons (e.g., essentially horizontal rebar 28). Additionally/alternatively, photovoltaic support member 24 may be a pre-cast concrete photovoltaic support member.

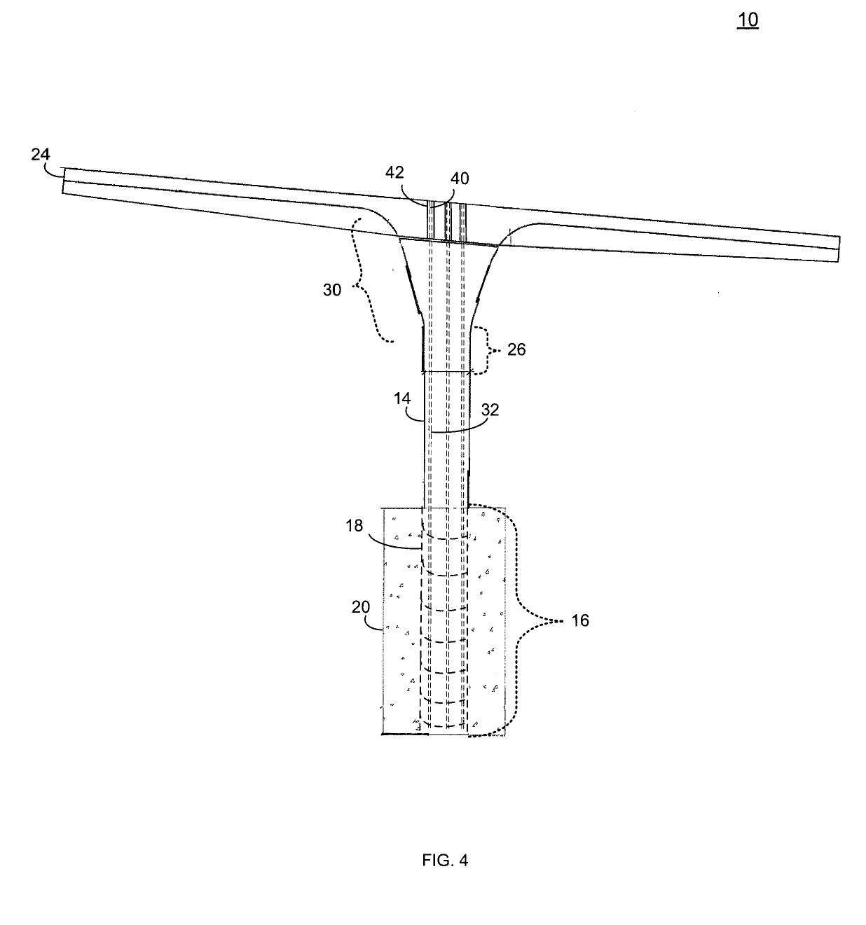

Referring also to FIG. 4, photovoltaic system 10 may include a rigid joint assembly (e.g., rigid joint assembly 30) that may be configured to rigidly couple the essentially vertical support member (e.g., essentially vertical support member 14) to the photovoltaic support member (e.g., photovoltaic support member 24). Rigid joint assembly 30 may be implemented in a number of fashions including, but not limited to: constructing rigid joint assembly 30 as an integrated top portion of essentially vertical support member 14, or as an interchangeable extension of essentially vertical support member 14.

Continuing with the above-stated example, essentially vertical support member 14 may include one or more essentially vertical rebar supports 32 (e.g., included within a rebar structural cage) that, when utilized in conjunction with, e.g., rigid joint assembly 30, may rigidly couple photovoltaic support member 24 to essentially vertical support member 14. Additionally, essentially vertical rebar supports 32 may be corrugated.

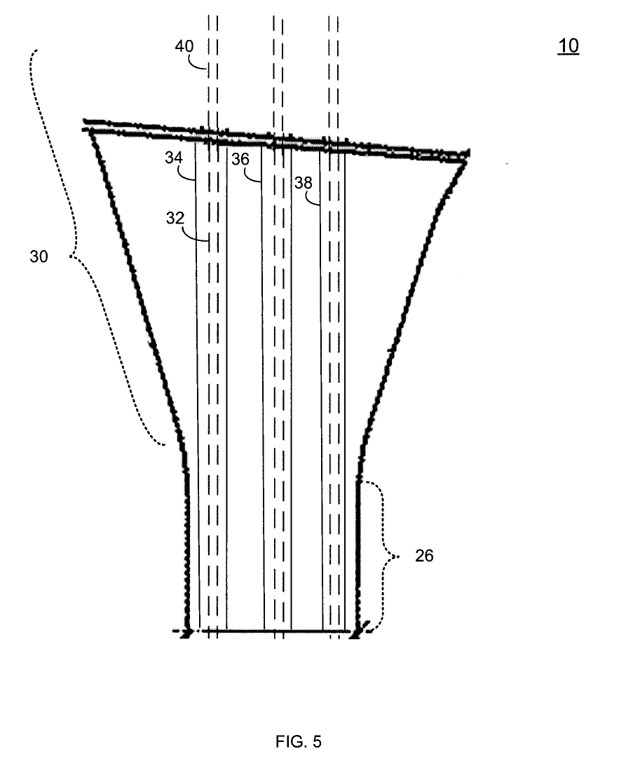

Further, and referring also to FIG. 5, the rigid joint assembly (e.g., rigid joint assembly 30) may include one or more sleeves (e.g., rigid joint sleeves 34, 36, 38), that may be configured to receive one or more reinforcement members (e.g., essentially vertical rebar supports 32). Alternatively, sleeves may not be utilized within rigid joint assembly 30 and e.g., the reinforcement members (e.g., essentially vertical rebar supports 32) may be cast within rigid joint assembly 30.

Accordingly, the coupling of photovoltaic support member 24 to essentially vertical support member 14 (e.g., via rigid joint assembly 30) may be accomplished by first threading protruding portion 40 of essentially vertical rebar supports 32 (e.g., protruding beyond second portion 26 of essentially vertical support member 14 and rigid joint assembly 36) through receiving sleeve 42 of photovoltaic support member 24.

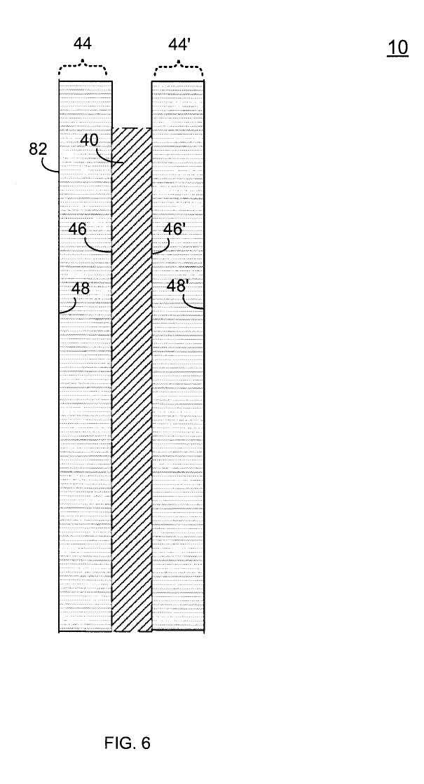

Additionally, and referring also to FIG. 6, a gap (e.g., gap 44/44′) may be defined between an outer periphery (e.g., outer reinforcement member periphery 46/46′) of at least one of the reinforcement members (e.g., protruding portion 40) and an inner periphery (e.g., inner sleeve periphery 48/48′) of at least one of the sleeves into which the at least one reinforcement members is positioned (e.g., receiving sleeve 42), wherein the gap is configured to be filled with a bonding agent. For example, gap 44/44′ may be filled with a cementitious bonding agent (e.g., grout) to create an enhanced coupling of photovoltaic support member 24 to essentially vertical support member 14 (e.g., via receiving sleeve 42 included within photovoltaic support member 24). If rigid joint assembly 30 is not an integral part of essentially vertical support member 14 and rigid joint assembly 30 includes rigid joint sleeves 34, 36, 38, a similar fastening methodology may be utilized to couple rigid joint assembly 30 to essentially vertical support member 14.

However, this is not to be construed as a limitation of the present disclosure, as photovoltaic support member 24 may be coupled to essentially vertical support member 14 (e.g., via rigid joint assembly 30) utilizing any suitable means (e.g., cartridge activated tools, hammer drills, etc.).

Additionally, the rigid joint assembly (e.g., rigid joint assembly 30) may be configured to provide non-perpendicular positioning of the photovoltaic support member (e.g., photovoltaic support member 24) with respect to the essentially vertical support member (e.g., essentially vertical support member 14). As is known to one of skill in the art, it may be desirable implement rigid joint assembly 30 in a manner that may enable photovoltaic support member 24 to be coupled to essentially vertical support member 14 at an angle (e.g., five degrees) to induce optimal reception of light (e.g., from the sun) and/or catalyze the run-off of water from photovoltaic support member 24. However, this is not to be construed as a limitation of this disclosure, as the angle may be established at any suitable degree.

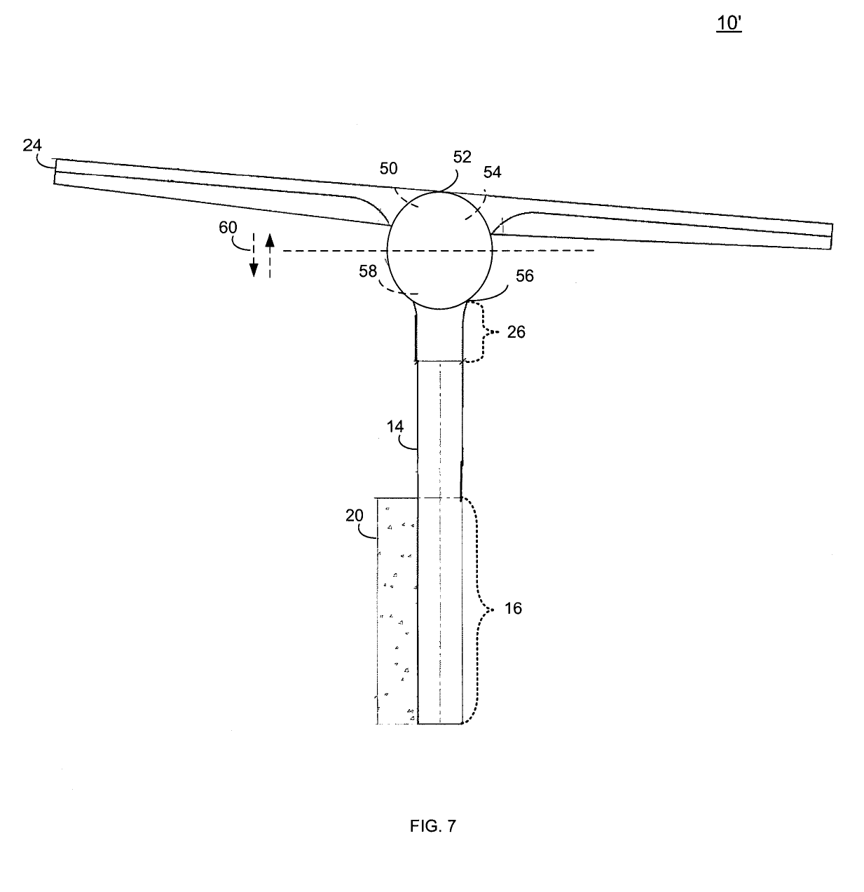

Alternatively, and referring also to FIGS. 7 & 8, there is shown an alternative embodiment photovoltaic system 10′ for absorbing light energy from a light source (e.g., the sun).

Photovoltaic system 10′ may include a pivotable joint assembly (e.g., pivotable joint assembly 50) that may be configured to pivotally couple the essentially vertical support member (e.g., essentially vertical support member 14) to the photovoltaic support member (e.g., photovoltaic support member 24). Pivotable joint assembly 50 may include a first rigid joint assembly (e.g., first rigid joint assembly 52) for rigidly affixing a first portion of the pivotable joint assembly (e.g., first portion of pivotable joint assembly 54) to the photovoltaic support member (e.g., photovoltaic support member 24). Further, pivotable joint assembly 50 may also include a second rigid joint assembly (e.g., second rigid joint assembly 56) for rigidly affixing a second portion of the pivotable joint assembly (second portion of pivotable joint assembly 58) to the essentially vertical support member (e.g., essentially vertical support member 14).

Similar to the implementation of rigid joint assembly 30, second portion 26 of essentially vertical support member 14 may include one or more essentially vertical rebar supports 32 that, when utilized in conjunction with, e.g., second rigid joint assembly 56 of pivotable joint assembly 50, may pivotally couple photovoltaic support member 24 to essentially vertical support member 14.

For example, pivotable joint assembly 50 may enable photovoltaic support member 24 to pivot about a range of degrees to induce optimal reception of light (e.g., from the sun) and/or catalyze the run-off of water from photovoltaic support member 24 (as shown by pivot arrows 60). Accordingly, the coupling of photovoltaic support member 24 to essentially vertical support member 14 (e.g., via pivotable joint assembly 50) may be accomplished by e.g., positioning a second protruding portion 64 of rebar support 62 (e.g., protruding beyond first portion 54 of pivotable joint assembly 50) through a sleeve (e.g., receiving sleeve 42) of photovoltaic support member 24.

Similar to the configuration involving rigid joint assembly 30, a gap may be defined between an outer periphery of at least one of the reinforcement members (e.g., the protruding portion 64 of rebar support 62) and an inner periphery of at least one of the sleeves into which the reinforcement members is positioned (e.g., receiving sleeve 42 of photovoltaic support member 24), wherein the gap may be configured to be filled with a bonding agent. For example, the gap may be filled with a cementitious bonding agent (e.g., grout) to create an enhanced coupling of photovoltaic support member 24 to essentially vertical support member 14 (e.g., via pivotable joint assembly 50).

If pivotable joint assembly 50 is not an integral part of essentially vertical support member 14 and pivotable joint assembly 50 includes rigid joint sleeves, a similar fastening methodology may be utilized to couple pivotable joint assembly 50 to essentially vertical support member 14.

However, this is not to be construed as a limitation of the present disclosure, as photovoltaic support member 24 may be coupled to essentially vertical support member 14 (e.g., via pivotable joint assembly 50) utilizing any suitable means (e.g., cartridge activated tools, hammer drills, etc.).

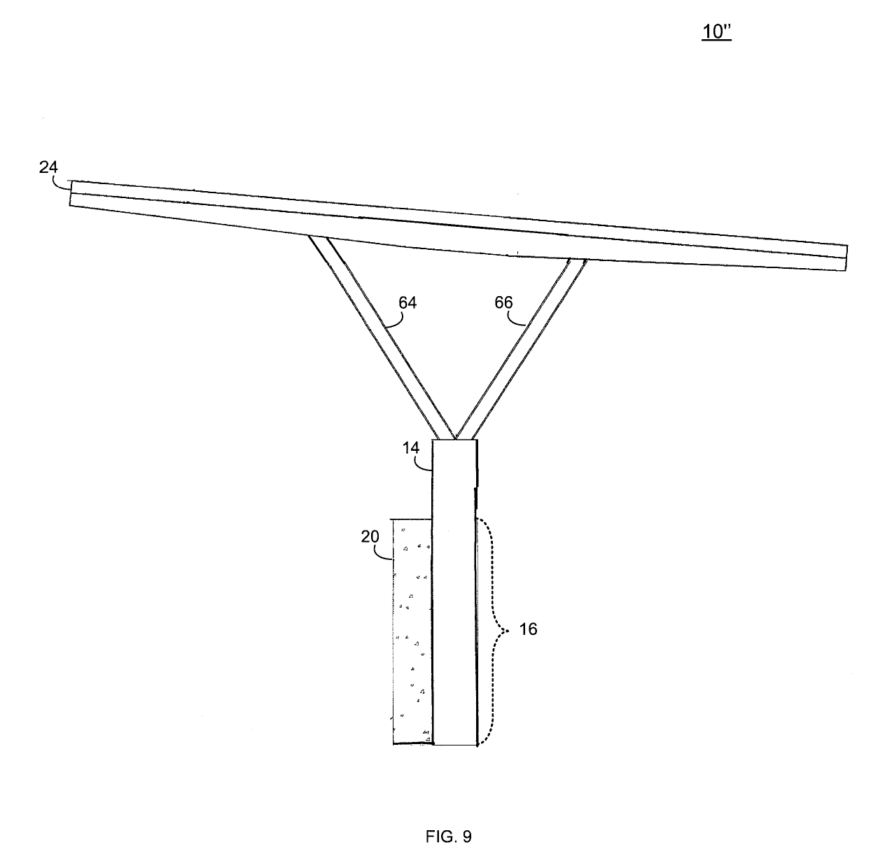

Additionally/alternatively, and referring also to FIG. 9, there is shown an alternative embodiment photovoltaic system 10″ for absorbing light energy from a light source (e.g., the sun).

Photovoltaic system 10″ may include a plurality of obliquely angled support members (e.g., obliquely angled support members 64/66) that may be configured to be affixed to the essentially vertical support member (e.g., essentially vertical support member 14) of, e.g., photovoltaic system 10″, wherein the photovoltaic support member (e.g., photovoltaic support member 24) may be configured to be affixed to the plurality of obliquely angled support members. Obliquely angled support members 64/66 may be constructed out of any material suitable to support photovoltaic support member 24. For example, materials that obliquely angled support members 64/66 may be constructed out of include, but are not limited to, concrete (e.g., pre-tensioned concrete, bonded post-tensioned concrete, unbonded post-tensioned concrete, and pre-cast concrete), steel, aluminum, and wood.

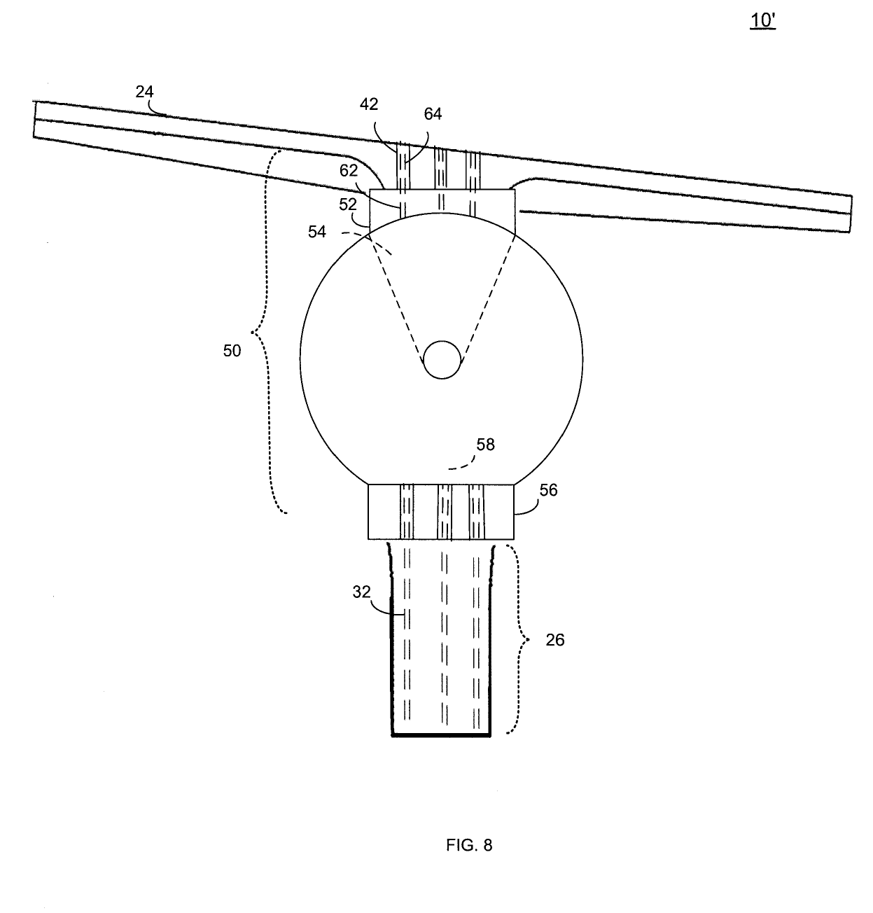

Similar to the implementation of rigid joint assembly 30 and pivotable joint assembly 50, a plurality of obliquely angled support members (e.g., obliquely angled support members 64/66) may be affixed (rigidly or pivotally) to essentially vertical support member 14, which may also be affixed (rigidly or pivotally) to photovoltaic support member 24. For example, pivotable joint assembly 50 (as discussed in FIG. 8) may allow the angle at which obliquely angled support members 64/66 are affixed to essentially vertical support member 14 to be varied to enable photovoltaic support member 24 to induce optimal reception of light (e.g., from the sun) and/or catalyze the run-off of water from photovoltaic support member 24.

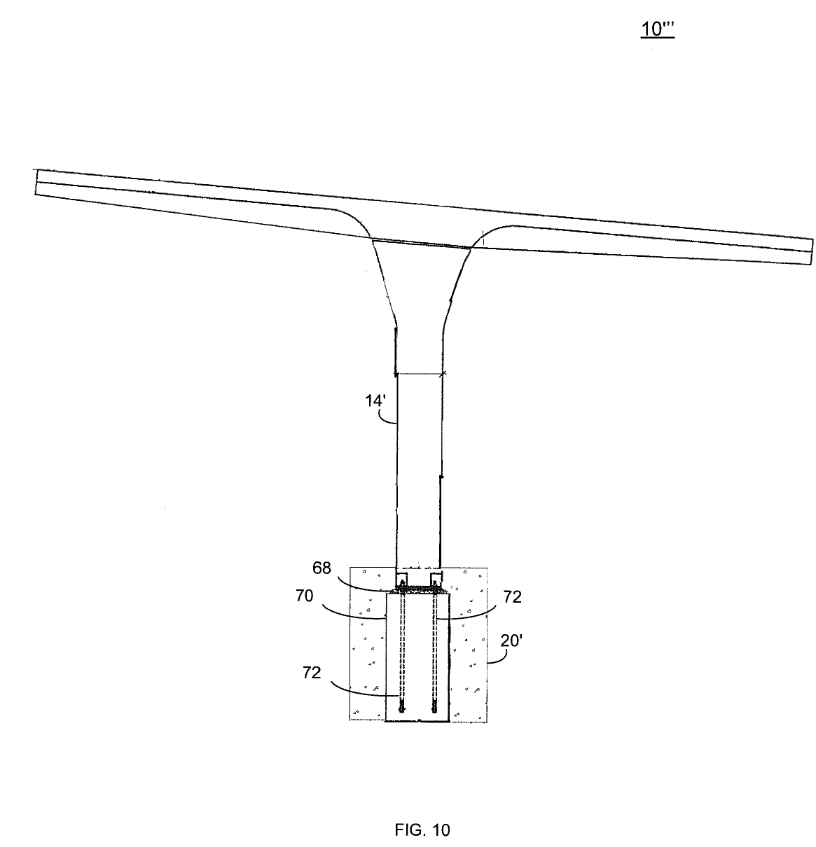

Referring also to FIG. 10, there is shown an alternative embodiment photovoltaic system 10″′ for absorbing light energy from a light source (e.g., the sun).

Photovoltaic system 10″′ may include an essentially vertical support member (e.g., essentially vertical support member 14′) that may be constructed, at least in part, of concrete, wherein the essentially vertical support member may include a flange assembly (e.g., flange assembly 68) that may be configured to releasably couple the essentially vertical support member to a base (e.g., base 70). Flange assembly 68 may be a structural object that may be utilized for attachment to another object (e.g., a pipe flange), and may be, e.g., welded and/or bolted to essentially vertical support member 14′. However, this is not to be construed as a limitation of this disclosure, as flange assembly 68 may be affixed to essentially vertical support member 14′ in any number of suitable means. For example, flange assembly 68 may be a circumferential flange (not shown) that may be bolted to essentially vertical support member 14′ using one or more through-bolts (not shown).

Additionally, flange bolts 72 may be utilized in conjunction with flange assembly 68 to, e.g., releasably couple essentially vertical support member 14′ to base 70. As is known in the art, base 70 may be a foundational structure (e.g., a structure that may transfer loads to the earth), which may be, at least in part, submerged within the ground (e.g., ground 20′).

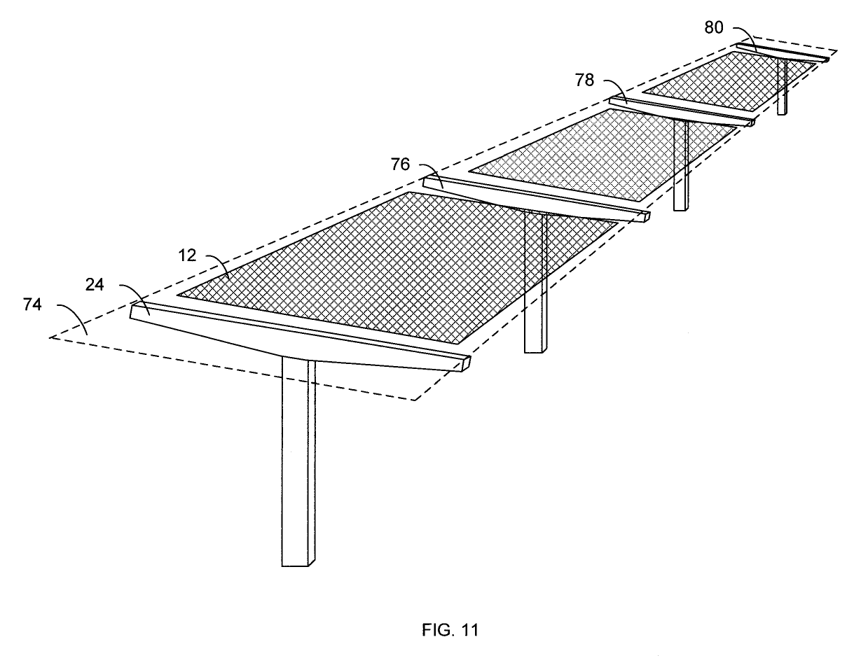

Additionally/alternatively, and referring also to FIG. 11, photovoltaic support member 24 may be affixed to photovoltaic support structure 74 that may span adjacent photovoltaic support members (e.g., photovoltaic support members 76, 78, 80) to which photovoltaic components 12 may be affixed. Examples of photovoltaic support structure 74 may include, but are not limited to: C-channels; J-channels; square tubes; round tubes; and rectangular tubes. However, this is not to be construed as a limitation of this disclosure, as photovoltaic components 12 may be directly affixed to, e.g., photovoltaic support member 24 (which may be affixed to, e.g., essentially vertical support member 14).

The diagrams in the above-described figures illustrate the various features of the concrete photovoltaic system. It should be noted that, in some alternative implementations, the configuration of the photovoltaic system (e.g., photovoltaic system 10/10′/10″/10″′) may combine any of the various aspects described herein. For example, while photovoltaic system 10 has been described without utilizing flange assembly 68 and base 70, this is not to be construed as a limitation of this disclosure. Accordingly, the various features shown in each figure of the concrete photovoltaic system may be mixed and matched without limiting the scope and/or deviating from the spirit of the concrete photovoltaic system.

Having thus described the invention of the present application in detail and by reference to embodiments thereof, it will be apparent that modifications and variations are possible without departing from the scope of the invention defined in the appended claims.

What is claimed is:

1. A concrete photovoltaic structure comprising:
an essentially vertical support member constructed, at least in part, of concrete, wherein the essentially vertical support member includes a first portion configured to be received, at least in part, within a footing; and
a photovoltaic support member constructed, at least in part, of concrete, wherein the photovoltaic support member is configured to be affixed to a second portion of the essentially vertical support member.

2. The concrete photovoltaic structure of claim 1 further comprising:
a rigid joint assembly configured to rigidly couple the essentially vertical support member to the photovoltaic support member.

3. The concrete photovoltaic structure of claim 2 wherein the rigid joint assembly includes one or more sleeves configured to receive one or more reinforcement members.

4. The concrete photovoltaic structure of claim 3 wherein at least one of the sleeves are positioned within the photovoltaic support member and at least one of the reinforcement members are configured to be positioned within the essentially vertical support member.

5. The concrete photovoltaic structure of claim 3 wherein a gap is defined between an outer periphery of at least one of the reinforcement members and an inner periphery of at least one of the sleeves into which the at least one reinforcement member is positioned, wherein the gap is configured to be filled with a bonding agent

6. The concrete photovoltaic structure of claim 5 wherein the bonding agent is a cementitious bonding agent.

7. The concrete photovoltaic structure of claim 2 wherein the rigid joint assembly is configured to provide non-perpendicular positioning of the photovoltaic support member with respect to the essentially vertical support member.

8. The concrete photovoltaic structure of claim 1 further comprising:
a pivotable joint assembly configured to pivotally couple the essentially vertical support member to the photovoltaic support member.

9. The concrete photovoltaic structure of claim 8 wherein the pivotable joint assembly includes a first rigid joint assembly for rigidly affixing a first portion of the pivotable joint assembly to the photovoltaic support member.

10. The concrete photovoltaic structure of claim 9 wherein the pivotable joint assembly includes a second rigid joint assembly for rigidly affixing a second portion of the pivotable joint assembly to the essentially vertical support member.

11. The concrete photovoltaic structure of claim 1 wherein the essentially vertical support member is a pre-cast concrete essentially vertical support member.

12. The concrete photovoltaic structure of claim 1 wherein the essentially vertical support member is a pre-stressed concrete essentially vertical support member.

13. The concrete photovoltaic structure of claim 1 wherein the essentially vertical support member includes a plurality of obliquely angled support members, wherein the photovoltaic support member is configured to be affixed to the plurality of obliquely angled support members.

14. The concrete photovoltaic structure of claim 13 wherein the plurality of obliquely angled support members are constructed, at least in part, of metallic material.

15. The concrete photovoltaic structure of claim 1 wherein the footing is a tubular footing.

16. The concrete photovoltaic structure of claim 1 wherein the photovoltaic support member is constructed, at least in part, of pre-cast concrete.

17. The concrete photovoltaic structure of claim 1 wherein the photovoltaic support member is constructed, at least in part, of pre-stressed concrete.

18. A concrete photovoltaic structure comprising:
an essentially vertical support member constructed, at least in part, of concrete, wherein the essentially vertical support member includes a first portion configured to be received, at least in part, within a footing;
a photovoltaic support member constructed, at least in part, of concrete, wherein the photovoltaic support member is configured to be affixed to a second portion of the essentially vertical support member; and
a rigid joint assembly configured to rigidly couple the essentially vertical support member to the photovoltaic support member, wherein the essentially vertical support member is a pre-cast concrete essentially vertical support member.

19. The concrete photovoltaic structure of claim 18 wherein the rigid joint assembly includes one or more sleeves configured to receive one or more reinforcement members.

20. The concrete photovoltaic structure of claim 19 wherein at least one of the sleeves are positioned within the photovoltaic support member and at least one of the reinforcement members are configured to be positioned within the essentially vertical support member.

21. A concrete photovoltaic structure comprising:
an essentially vertical support member constructed, at least in part, of concrete, wherein the essentially vertical support member includes a first portion configured to be received, at least in part, within a footing;
a photovoltaic support member constructed, at least in part, of concrete, wherein the photovoltaic support member is configured to be affixed to a second portion of the essentially vertical support member; and
a pivotable joint assembly configured to pivotally couple the essentially vertical support member to the photovoltaic support member, wherein the essentially vertical support member is a pre-cast concrete essentially vertical support member.

22. The concrete photovoltaic structure of claim 21 wherein the pivotable joint assembly includes a first rigid joint assembly for rigidly affixing a first portion of the pivotable joint assembly to the photovoltaic support member.

23. The concrete photovoltaic structure of claim 22 wherein the pivotable joint assembly includes a second rigid joint assembly for rigidly affixing a second portion of the pivotable joint assembly to the essentially vertical support member.
